(19) United States
(12) Patent Application Publication
(10) Pub. No.: US 2026/0206390 A1
(43) Pub. Date: Jul. 16, 2026

(54) DISPLAY DEVICE AND ELECTRONIC DEVICE INCLUDING THE SAME

(71) Applicant: Samsung Display Co., Ltd., Yongin-si (KR)

(72) Inventors: Dae Ho SONG, Yongin-si (KR); Seung Hun KIM, Yongin-si (KR); Sung Hwan WON, Yongin-si (KR)

(21) Appl. No.: 19/377,737

(22) Filed: Nov. 3, 2025

(30) Foreign Application Priority Data
Jan. 10, 2025 (KR) 10-2025-0004148

(51) Int. Cl. H10H 29/49; H10H 29/853; H10H 29/855

(52) U.S. Cl. CPC H10H 29/49; H10H 29/853; H10H 29/855

(57) ABSTRACT

A display device includes a display panel, a driving member providing a first driving signal, and a cover substrate covering the display panel and the driving member, and including a light-transmitting layer including a facing surface facing the display panel and the driving member, and a display surface opposite the facing surface, first and second passivation layers sequentially on the facing surface along a thickness direction from the display surface toward the opposite surface, a signal-transmitting element electrically connecting the display panel and the driving member, and including transmitting lines between the first and second passivation layers, and transmitting pads connected to the transmitting lines by penetrating the second passivation layer, and a light-blocking layer between the light-transmitting layer and the first passivation layer, overlapping the signal-transmitting element in the thickness direction, and defining an opening overlapping an entirety of a display area in the thickness direction.

### CROSS-REFERENCE TO RELATED APPLICATION

The present application claims priority to, and the benefit of, Korean Patent Application No. 10-2025-0004148, filed on January 10, 2025, in the Korean Intellectual Property Office, the entire disclosure of which is incorporated herein by reference.

### BACKGROUND

### 1. Field

The present disclosure relates to a display device, and an electronic device including the same.

### 2. Description of the Related Art

A display device is a device for displaying an image. The display device may include a display panel displaying an image, and a cover substrate that protects the display panel from external impact or the like. When other components (e.g., electrodes, lines, etc.) located outside of a display area in which the image is displayed are prominently visually recognized by the user of the display device, the visibility of the display device may be degraded, and thus the display quality of the display device may be degraded.

### SUMMARY

The present disclosure provides a display device with improved display quality.

A display device according to embodiments of the present disclosure includes a display panel including a display area for displaying an image, and a peripheral area around the display area, a driving member to provide a first driving signal, and a cover substrate covering the display panel and the driving member, and including a light-transmitting layer including a facing surface facing the display panel and the driving member, and a display surface opposite to the facing surface, a first passivation layer and a second passivation layer sequentially on the facing surface along a thickness direction from the display surface toward the opposite surface, a signal-transmitting element electrically connecting the display panel and the driving member, and including transmitting lines between the first passivation layer and the second passivation layer, and transmitting pads connected to the transmitting lines by penetrating the second passivation layer, and a light-blocking layer between the light-transmitting layer and the first passivation layer, overlapping the signal-transmitting element in the thickness direction, and defining an opening overlapping an entirety of the display area in the thickness direction.

The display panel may further include sub-pixels in the display area, and first pads in the peripheral area, and electrically connected to the sub-pixels, and wherein the driving member includes second pads including 2-1-th pads for outputting the first driving signal.

The transmitting pads may include first transmitting pads electrically connected to the first pads, and second transmitting pads electrically connected to the second pads, wherein the transmitting lines include first transmitting lines electrically connecting 2-1-th transmitting pads electrically connected to the 2-1-th pads to the first transmitting pads.

The first pads and the first transmitting pads may overlap in the thickness direction, wherein the second pads and the second transmitting pads overlap in the thickness direction.

The display device may further include first conductive connecting members between the first pads and the first transmitting pads, and second conductive connecting members between the second pads and the second transmitting pads.

Melting points of the first conductive connecting members and the second conductive connecting members may be greater than or equal to about 110℃ and less than or equal to about 150℃.

The display panel may further include data lines electrically connected to the first pads in the peripheral area and electrically connected to the sub-pixels in the display area.

The first driving signal may include a data signal transmitted from the driving member to the display panel through the signal-transmitting element.

The display device may further include a flexible circuit substrate to provide a second driving signal, wherein the cover substrate covers the flexible circuit substrate.

The display panel and the flexible circuit substrate may be electrically connected to each other through the signal-transmitting element.

The flexible circuit substrate may be bent, and may include at least a portion overlapping at least a portion of the driving member in the thickness direction.

The display panel may include sub-pixels in the display area, a scan driver in the peripheral area, and electrically connected to the sub-pixels, and third pads in the peripheral area, and electrically connected to the sub-pixels or the scan driver, and wherein the flexible circuit substrate includes fourth pads configured to output the second driving signal.

The transmitting pads may include third transmitting pads electrically connected to the third pads, and fourth transmitting pads electrically connected to the fourth pads, wherein the transmitting lines include second transmitting lines electrically connecting the third transmitting pads and the fourth transmitting pads.

The third pads and the third transmitting pads may overlap in the thickness direction, wherein the fourth pads and the fourth transmitting pads overlap in the thickness direction.

The display device may further include third conductive connecting members between the third pads and the third transmitting pads, and fourth conductive connecting members between the fourth pads and the fourth transmitting pads.

Melting points of the third conductive connecting members and the fourth conductive connecting members may be greater than or equal to about 110℃ and less than or equal to about 150℃.

The display panel may include at least one first power line, at least one second power line, and at least one connecting line, wherein, in the peripheral area, the third pads are electrically connected to the first power line, the second power line, or the connecting line, and the connecting line is electrically connected to the scan driver, and wherein, in the display area, the first power line and the second power line are electrically connected to the sub-pixels.

The second driving signal may include a first power signal, a second power signal, and a scan-driving signal transmitted from the fourth pads to the third pads through the signal-transmitting element.

The light-blocking layer may overlap the peripheral area of the display panel and the driving member in the thickness direction.

An electronic device according to embodiments of the present disclosure includes a power supply module for supplying power, and a display device for receiving the power, and including a display panel including a display area for displaying an image, and a peripheral area around the display area, a driving member to provide a first driving signal, and a cover substrate covering the display panel and the driving member, and including a light-transmitting layer including a facing surface facing the display panel and the driving member, and a display surface opposite to the facing surface, a first passivation layer and a second passivation layer sequentially on the facing surface along a thickness direction from the display surface toward the opposite surface, a signal-transmitting element electrically connecting the display panel and the driving member, and including transmitting lines between the first passivation layer and the second passivation layer, and transmitting pads connected to the transmitting lines by penetrating the second passivation layer, and a light-blocking layer between the light-transmitting layer and the first passivation layer, overlapping the signal- transmitting element in the thickness direction, and defining an opening overlapping an entirety of the display area in the thickness direction.

In the display device according to embodiments of the present disclosure and the electronic device including the same, the signal-transmitting element may be substantially completely covered in the thickness direction by the light-blocking layer. Accordingly, it is possible to reduce or prevent degradation of display quality due to the signal-transmitting element being visually recognized.

In addition, the light-blocking layer may define the opening that overlaps at least entirety of the display area in the thickness direction. Accordingly, it is possible to reduce or prevent the likelihood of an image displayed in the display area being blocked by the light-blocking layer.

### BRIEF DESCRIPTION OF THE DRAWINGS

FIG. 1 is a block diagram illustrating a display device according to embodiments of the present disclosure.

FIG. 2 is a block diagram illustrating one or more embodiments of any one of sub-pixel among sub-pixels included in the display device of FIG. 1.

FIG. 3 is a plan view illustrating a display panel, a driving member, and a flexible circuit substrate included in the display device of FIG. 1.

FIG. 4 is an exploded perspective view illustrating a portion of the display panel of FIG. 3.

FIG. 5 is a plan view illustrating a cover substrate included in the display device of FIG. 1.

FIG. 6 is a cross-sectional view illustrating the cover substrate of FIG. 5.

FIG. 7 is a cross-sectional view illustrating a signal transmission element included in the cover substrate of FIG. 6.

FIGS. 8 and 9 are plan views illustrating a state in which the display panel, the driving member, and the flexible circuit substrate of FIG. 3 are coupled to the cover substrate of FIG. 5.

FIG. 10 is a cross-sectional view taken along the line I1-I2 of FIG. 9.

FIG. 11 is a block diagram of an electronic device according to one or more embodiments.

FIG. 12 shows schematic views of various embodiments of an electronic device.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When "C to D" is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/- 5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

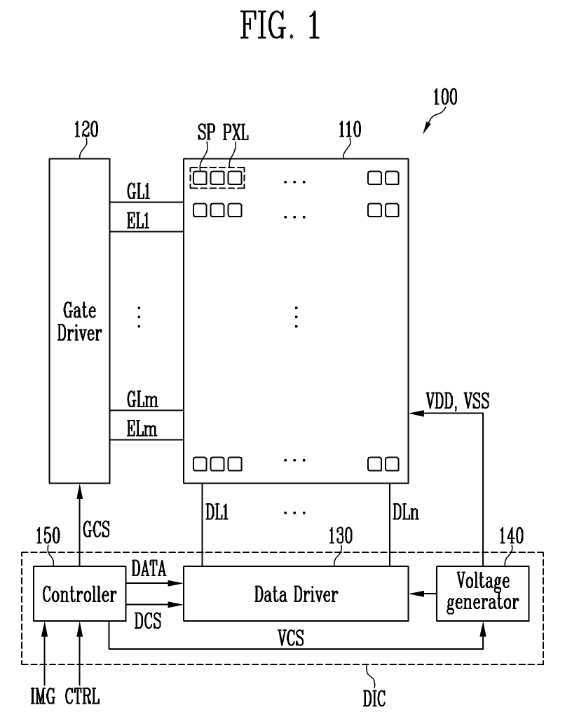

FIG. 1 is a block diagram illustrating a display device according to embodiments of the present disclosure.

Referring to FIG. 1, a display device 100 may include a display panel 110, a gate driver 120, a data driver 130, a voltage generator 140, and a controller 150.

The display panel 110 may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

Each of the sub-pixels SP may include at least one light-emitting element configured to generate light. Each of the sub-pixels SP may generate light of a color, such as red, green, blue, cyan, magenta, yellow, or the like. Two or more sub-pixels SP among the sub-pixels SP may constitute one pixel PXL. For example, as shown in FIG. 1, three sub-pixels SP may constitute one pixel PXL.

The gate driver 120 may be connected to the sub-pixels SP arranged along a row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal indicating the start of each frame, a horizontal synchronization signal for outputting gate signals in synchronization with the timing at which data signals are applied, or the like.

In embodiments, first to m-th light-emitting control lines EL1 to ELm connected to the sub-pixels SP in the row direction may be further provided. In this case, the gate driver 120 may include a light-emitting control driver configured to control the first to m-th light-emitting control lines EL1 to Elm, and the light-emitting control driver may operate under the control of the controller 150.

The gate driver 120 may be located on one side of the display panel 110. However, embodiments are not limited thereto. For example, the gate driver 120 may be divided into two or more drivers that are physically and/or logically separated, and such drivers may be respectively located on one side of the display panel 110 and on the other side of the display panel 110 that is opposite to the one side. In this way, the gate driver 120 may be located around the display panel 110 in various forms according to embodiments.

The data driver 130 may be connected to the sub-pixels SP arranged along a column direction through the first to n-th data lines DL1 to DLn. The data driver 130 may receive an image data DATA and a data control signal DCS from the controller 150. The data driver 130 may operate in response to the data control signal DCS. In embodiments, the data control signal DCS may include a source start pulse, a source shift clock, a source output enable signal, or the like.

The data driver 130 may apply data signals having gradation voltages corresponding to the image data DATA to the first to n-th data lines DL1 to DLn using voltages from the voltage generator 140. When a gate signal is applied to each of the first to m-th gate lines GL1 to GLm, data signals corresponding to the image data DATA may be applied to the data lines DL1 to DLm. Accordingly, corresponding sub-pixels SP may thus generate light corresponding to the data signals. Accordingly, an image may be displayed on the display panel 110.

In embodiments, the gate driver 120 and/or the data driver 130 may include CMOS (complementary metal-oxide semiconductor) circuit elements.

The voltage generator 140 may operate in response to a voltage control signal VCS from the controller 150. The voltage generator 140 may be configured to generate voltages, and may provide the generated voltages to components of the display device 100. For example, the voltage generator 140 may be configured to generate a voltages by receiving an input voltage from outside of the display device 100, by adjusting the received voltage, and by regulating the adjusted voltage.

The voltage generator 140 may generate a first power voltage VDD and a second power voltage VSS, and the generated first and the second power voltages VDD and VSS may be provided to the sub-pixels SP. The first power voltage VDD may have a relatively high voltage level, and the second power voltage VSS may have a lower voltage level than the first power voltage VDD. In other embodiments, the first power voltage VDD or the second power voltage VSS may be provided by an external device of the display device 100.

In addition, the voltage generator 140 may generate various voltages. For example, the voltage generator 140 may generate an initialization voltage applied to the sub-pixels SP. For example, in a sensing operation for sensing electrical characteristics of transistors and/or light-emitting elements of the sub-pixels SP, a reference voltage may be applied to the first to n-th data lines DL1 to DLn, and the voltage generator 140 may generate the reference voltage.

The controller 150 may control various operations of the display device 100. The controller 150 may receive an input image data IMG and a control signal CTRL for controlling the input image data IMG from outside. The controller 150 may provide the gate control signal GCS, the data control signal DCS, and a voltage control signal VCS in response to the control signal CTRL.

The controller 150 may output the image data DATA by converting the input image data IMG to be suitable for the display device 100 or the display panel 110. In embodiments, the controller 150 may output the image data DATA by aligning the input image data DATA to fit the sub-pixels SP in rows.

Two or more components among the data driver 130, the voltage generator 140, and the controller 150 may be integrated in one integrated circuit. For example, as shown in FIG. 1, the data driver 130, the voltage generator 140, and the controller 150 may be included in a driver integrated circuit DIC. In this case, the data driver 130, the voltage generator 140, and the controller 150 may be functionally distinct components within one driver integrated circuit DIC. For another example, at least one of the data driver 130, the voltage generator 140, or the controller 150 may be provided as a component separated from the driver integrated circuit DIC.

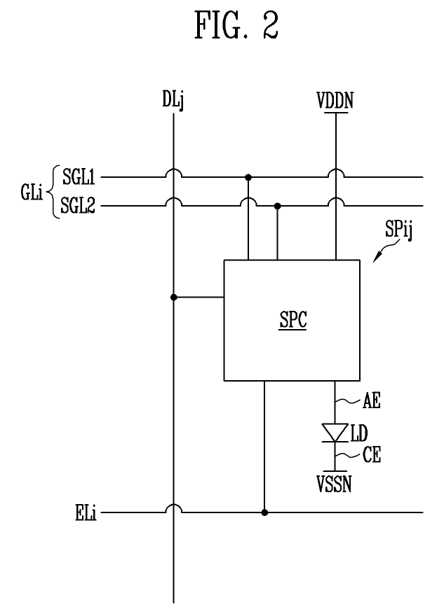

FIG. 2 is a block diagram illustrating one or more embodiments of any one of sub-pixel among sub-pixels included in the display device of FIG. 1.

In FIG. 2, among the sub-pixels SP in FIG. 1, a sub-pixel SPij arranged in an i-th row (i is integer that is greater than or equal to 1 and that is less than or equal to m) and the j-th column (j is an integer that is larger than or equal to 1 and that is less than or equivalent to n) is shown.

Referring to FIG. 2, the sub-pixel SPij may include a sub-pixel circuit SPC and a light-emitting element LD.

The light-emitting element LD may be connected between a first power voltage node VDDN and a second power voltage node VSSN. The first power voltage node VDDN may be a node for transmitting the first power voltage VDD of FIG. 1, and the second power voltage node VSSN may be a node for transmitting the second power voltage VSS of FIG. 1.

An anode electrode AE of the light-emitting element LD may be connected to the first power voltage node VDDN through the sub-pixel circuit SPC. For example, the anode electrode AE of the light-emitting element LD may be connected to the first power voltage node VDDN through one or more transistors included in the sub-pixel circuit SPC. A cathode electrode CE of the light-emitting element LD may be connected to the second power voltage node VSSN.

The sub-pixel circuit SPC may be connected to an i-th gate line GLi among the first to m-th gate lines GL1 to GLm of FIG. 1, an i-th light-emitting control line ELi among the first to n-th light-emitting control lines EL1 to ELm of FIG. 1 and a j-th data line DLj among the first to n-th data lines DL1 to DLn of FIG. 1. The sub-pixel circuit SPC may control the light-emitting element LD according to the signals received through these signal lines.

The sub-pixel circuit SPC may operate in response to a gate signal received through the i-th gate line GLi. The i-th gate line GLi may include one or more sub-gate lines. In embodiments, as shown in FIG. 2, the i-th gate line GLi may include first and second sub-gate lines SGL1 and SGL2. The sub-pixel circuit SPC may operate in response to gate signals received through the first and the second sub-gate lines SGL1 and SGL2. As such, when the i-th gate line GLi includes two or more sub-gate lines, the sub-pixel circuit SPC may operate in response to gate signals received through the corresponding sub-gate lines.

The sub-pixel circuit SPC may operate in response to a light-emitting control signal received through the i-th light-emitting control line ELi. In embodiments, the i-th light-emitting control line ELi may include one or more sub-light-emitting control lines. In case that the i-th light-emitting control line ELi includes two or more sub-light-emitting control lines, the sub-pixel circuit SPC may operate in response to light-emitting control signals received through those sub-light-emitting control lines.

The sub-pixel circuit SPC may receive a data signal through the j-th data line DLj. The sub-pixel circuit SPC may store a voltage corresponding to the data signal in response to at least one of the gate signals received through the first and the second sub-gate lines SGL1 and SGL2. In response to the light-emitting control signal received through the i-th light-emitting control line ELi, the sub-pixel circuit SPC may adjust the current flowing from the first power voltage node VDDN to the second power voltage node VSSN through the light-emitting element LD according to the stored voltage. Accordingly, the light-emitting element LD may generate light of a luminance corresponding to the data signal.

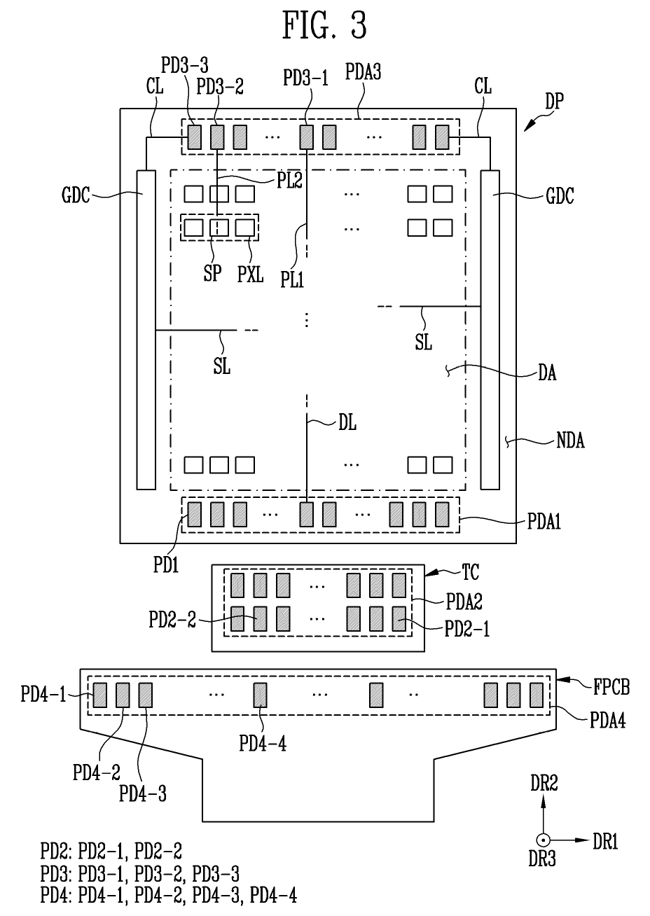

FIG. 3 is a plan view illustrating a display panel, a driving member, and a flexible circuit substrate included in the display device of FIG. 1.

Referring to FIG. 3, in one or more embodiments, the display panel 110 of FIG. 1 may be implemented with a display panel DP of FIG. 3, the data driver 130 of FIG. 1 may be implemented with a driving member TC of FIG. 3, and the voltage generator 140 and/or the controller 150 of FIG. 1 may be implemented with a flexible circuit substrate FPCB of FIG. 3.

The display panel DP may include a display area DA, and a peripheral area NDA around the display area DA. The display area DA may be an area for displaying an image. The peripheral area NDA may be an area substantially not displaying an image.

The display panel DP may include sub-pixels SP located in the display area DA. The sub-pixels SP may be arranged in a matrix form along a first direction DR1 and along a second direction DR2 crossing the first direction DR1. However, embodiments are not limited thereto. For example, the sub-pixels SP may be arranged in a zigzag form along the first direction DR1 and the second direction DR2. The first direction DR1 may be the row direction, and the second direction DR2 may be the column direction. Two or more sub-pixels SP among the sub-pixels SP may constitute one pixel PXL.

The display panel DP may include first pads PD1 located in the peripheral area NDA. The first pads PD1 may serve to provide at least a portion of an electrical connection path between the display panel DP and other components (e.g., the driving member TC). In one or more embodiments, the first pads PD1 may be arranged along the first direction DR1, and these first pads PD1 may be referred to as a first pad array PDA1.

The first pads PD1 may be electrically connected to the sub-pixels SP. For example, the display panel DP may include a data line DL, and the data line DL may be electrically connected to one first pad PD among the first pads PD1 in the peripheral area NDA, and may be electrically connected to the sub-pixels SP arranged along the column direction (e.g., the second direction DR2) in the display area DA.

In FIG. 3, only one data line DL is shown for convenience of description, but the data line DL may be provided in plural. In this case, a plurality of data lines DL may be electrically connected to the first pads PD1 in the peripheral area NDA. For example, the plurality of data lines DL may be connected in a one-to-one correspondence to the first pads PD1 in the peripheral area NDA. The plurality of data lines DL may be electrically connected to the sub-pixels SP in the display area DA. For example, the plurality of data lines DL may be electrically connected to the sub-pixels SP arranged along the column direction in the display area DA, respectively.

The display panel DP may include third pads PD3 located in the peripheral area NDA, and a scan driver (e.g., a scan-driving circuit part) GDC located in the peripheral area NDA.

The scan driver GDC may serve substantially the same role as the gate driver 120 described with reference to FIG. 1. The scan driver GDC may be spaced apart from the first pad array PDA1. Although FIG. 3 illustrates one or more embodiments in which the scan driver GDC is located in each of both sides of the display area DA, embodiments are not limited thereto. For example, the scan driver GDC may be located in only one side of the display area DA.

In one or more embodiments, the display panel DP may include a scan line SL, and the scan line SL may be electrically connected to the scan driver GDC in the peripheral area, and may be electrically connected to the sub-pixels arranged along the row direction (e.g., the first direction DR1) in the display area DA. The scan line SL may serve substantially the same role as the first to m-th gate lines GL1 to GLm and/or the first to m-th light-emitting control lines EL1 to Elm described with reference to FIG. 1.

In FIG. 3, an example of only one scan line SL connected to each of the scan drivers GDC is shown for convenience of description, but the scan line SL may be provided in plural in each of the scan drivers GDC. In this case, in one or more embodiments, scan lines SL connected to the scan driver GDC located in the left side of the display area DA based on illustration of FIG. 3 may serve as the first to m-th gate lines GL1 to GLm, and scan lines SL connected to the scan driver GDC located in the right side of the display area DA based on illustration of FIG. 3 may serve as the first to m-th light-emitting control lines EL1 to Elm. However, embodiments are not limited thereto.

The third pads PD3 may serve to provide at least a portion of an electrical connection path between the display panel DP and other components (e.g., flexible circuit substrate FPCB). In one or more embodiments, the third pads PD3 may be arranged along the first direction DR1, and these third pads PD3 may be referred to as a third pad array PDA3. The third pad array PDA3 may be spaced apart from the first pad array PDA1 and the scan driver GDC.

In one or more embodiments, the display panel DP may include at least one first power line PL1, at least one second power line PL2, and at least one connecting line CL.

In the display area DA, the first power line PL1 may be electrically connected to the sub-pixels SP. In the display area DA, the second power line PL2 may be electrically connected to the sub-pixels SP. In one or more embodiments, at least one of the first power line PL1 or the second power line PL2 may have mesh-line form in which a plurality of power lines extending along the first direction DR1 and the second direction DR2 are cross-connected. In one or more embodiments, the first power line PL1 may serve to transmit the first power voltage VDD described with reference to FIG. 1, and the second power line PL2 may serve to transmit the second power voltage VSS described with reference to FIG. 1.

In the peripheral area NDA, the connecting line CL may be electrically connected to the scan driver GDC. In one or more embodiments, the connecting line CL may serve to transmit the gate control signal GCS described with reference to FIG. 1. In one or more embodiments, the connecting line CL may not overlap (e.g., may be separated from (in plan view)) the display area DA.

In one or more embodiments, each of the third pads PD3 may be electrically connected to the first power line PL1, the second power line PL2, or the connecting line CL in the peripheral area NDA. Accordingly, each of the third pads PD3 may be electrically connected to the sub-pixels SP or the scan driver GDC.

In one or more embodiments, the third pads PD3 may include a 3-1-th pad PD3-1, a 3-2-th pad PD3-2, and a 3-3-th pad PD3-3.

The 3-1-th pad PD3-1 may be a pad electrically connected to the first power line PL1 among the third pads PD3. In one or more embodiments, the first power line PL1 may be provided in plural, and the 3-1-th pad PD3-1 may be provided in plural so as to correspond to the first power lines PL1 in one-to-one fashion.

The 3-2-th pad PD3-2 may be a pad electrically connected to the second power line PL2 among the third pads PD3. In one or more embodiments, the second power line PL2 may be provided in plural, and the 3-2-th pad PD3-2 may be provided in plural so as to correspond one-to-one to the second power lines PL2.

The 3-3-th pad PD3-3 may be a pad electrically connected to the connecting line CL among the third pads PD3. In one or more embodiments, the connecting line CL may be provided in plural, and the 3-3-th pad PD3-3 may be provided in plural so as to the connecting lines CL in correspond one-to-one fashion.

The driving member TC may provide a first driving signal. In one or more embodiments, the driving member TC may serve substantially the same role as the data driver 130 described with reference to FIG. 1. In this case, the first driving signal may include the data signal having gradation voltages corresponding to the image data DATA described with reference to FIG. 1.

In one or more embodiments, the driving member TC may include second pads PD2. The second pads PD2 may be arranged along the first direction DR1 and the second direction DR2, and these second pads PD2 may be referred to as a second pad array PDA2. The second pads PD2 may serve to provide at least a portion of an electrical connection path between the driving member TC and other components (e.g., display panel DP).

In one or more embodiments, the second pads PD2 may include a 2-1-th pad PD2-1 and a 2-2-th pad PD2-2.

The 2-1-th pad PD2-1 may be a pad for outputting the first driving signal among the second pads PD2. In one or more embodiments, the 2-1-th pad PD2-1 may be provided in plural. In this case, in one or more embodiments, the number of the 2-1-th pads PD2-1 may be same as the number of the first pads PD1.

The 2-2-th pad PD2-2 may be a pad for receiving another driving signal (e.g. the image data DATA and the data control signal DCS of FIG. 1) suitable for generating the first driving signal among the second pads PD2. In one or more embodiments, the 2-2-th pad PD2-2 may be provided in plural.

The flexible circuit substrate FPCB may provide a second driving signal. In one or more embodiments, the flexible circuit substrate FPCB may serve substantially the same role as the voltage generator 140 and the controller 150. In this case, the second driving signal may include the gate control signal GCS (e.g., a scan-driving signal), the image data DATA, the data control signal DCS, the first power voltage VDD (e.g., a first power signal), and the second power voltage VSS (e.g., a second power signal) described with reference to FIG. 1.

In one or more embodiments, the flexible circuit substrate FPCB may include fourth pads PD4 on which the second driving signal is provided (e.g., on which the second driving signal is outputted). The fourth pads PD4 may be arranged along the first direction DR1, and these fourth pads PD4 may be referred to as a fourth pad array PD4. The fourth pads PD4 may serve to provide at least a portion of an electrical connection path between the flexible circuit substrate FPCB and other components (e.g., the display panel DP and the driving member TC).

In one or more embodiments, the fourth pads PD4 may include a 4-1-th pad PD4-1, a 4-2-th pad PD4-2, a 4-3-th pad PD4-3, and a 4-4-th pad PD4-4.

The 4-1-th pad PD4-1 may be a pad for outputting the first power voltage VDD (e.g., the first power signal) among the fourth pads PD4. In one or more embodiments, the 4-1-th pad PD4-1 may be provided in plural.

The 4-2-th pad PD4-2 may be a pad for outputting the second power voltage VSS (e.g., the second power signal) among the fourth pads PD4. In one or more embodiments, the 4-2-th pad PD4-2 may be provided in plural.

The 4-3-th pad PD4-3 may be a pad for outputting the gate control signal GCS (e.g., the scan-driving signal) among the fourth pads PD4. In one or more embodiments, the 4-3-th pad PD4-3 may be provided in plural. In this case, in one or more embodiments, the number of the 4-3-th pads PD4-3 may be same as the number of the 3-3-th pads PD3-3.

The 4-4-th pad PD4-4 may be a pad for outputting the image data DATA or the data control signal DCS. In one or more embodiments, the 4-4-th pad PD4-4 may be provided in plural. In this case, in one or more embodiments, the number of the 4-4-th pads PD4-4 may be same as the number of the 2-2-th pads PD2-2.

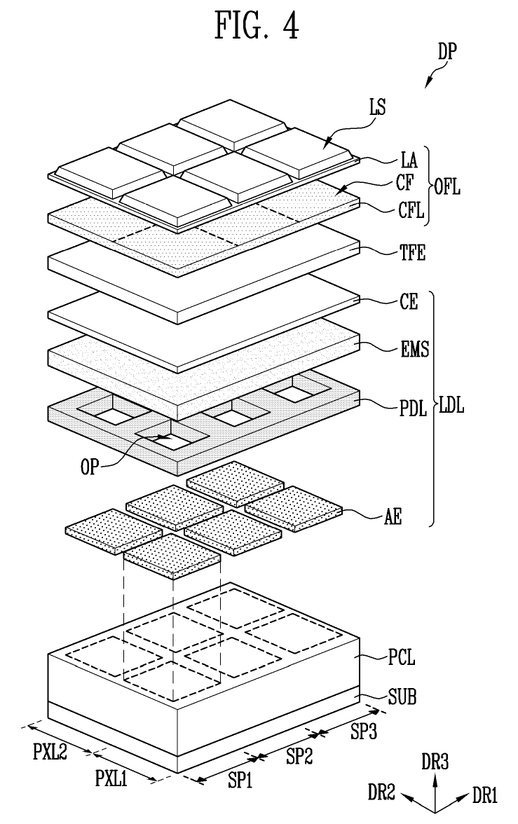

FIG. 4 is an exploded perspective view illustrating a portion of the display panel of FIG. 3.

In FIG. 4, a portion of the display panel DP corresponding to two pixels PXL1 and PXL2 among the pixels PXL in FIG. 3 is schematically illustrated for clarity and concise description. Other portions of the display panel DP corresponding to the remaining pixels PXL may also be configured as described below.

Referring to FIGS. 3 and 4, each of the first and the second pixels PXL1 and PXL2 may include first to third sub-pixels SP1, SP2, and SP3. However, embodiments are not limited thereto. For example, each of the first and the second pixels PXL1 and PXL2 may include four or more sub-pixels, or may include two sub-pixels.

In FIG. 4, the first to third sub-pixels SP1, SP2, and SP3 are shown as having square shapes, and as having the same areas as each other when viewed in a third direction DR3 crossing the first and the second directions DR1 and DR2, but embodiments are not limited thereto. The first to third sub-pixels SP1, SP2, and SP3 may be deformed to have various shapes and various areas.

The display panel DP may include a substrate SUB, a pixel circuit layer PCL, a light-emitting element layer LDL, an encapsulation layer TFE, and a light functional layer OFL.

In embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a silicon on insulator (SOI) layer, a semiconductor on insulator (SeOI) layer, or the like. Where the substrate SUB includes a silicon wafer substrate, a display device including various components formed on such substrate SUB may be referred to as an OLED on Silicon (OLEDoS) display device. The OLEDoS display device may implement the sub-pixels SP with a relatively high degree of integration, and thus may be used as a display screen of devices located very close to the user’s eyes, such as a head mounted display (HMD), a virtual reality (VR) device, a mixed reality (MR) device, and an augmented reality (AR) device. In other embodiments, the substrate SUB may include a glass substrate or a polyimide (PI) substrate.

The pixel circuit layer PCL may be located on the substrate SUB. The substrate SUB and/or the pixel circuit layer PCL may include insulation layers, and conductive patterns respectively located between the insulation layers. The conductive patterns of the pixel circuit layer PCL may function as at least a portion of circuit elements, lines, electrodes, or the like. The conductive patterns may include various types of conductive materials (e.g., copper).

The circuit elements may constitute a sub-pixel circuit SPC (refer to FIG. 2) of each of the first to third sub-pixels SP1, SP2, and SP3. The sub-pixel circuit SPC may include transistors and at least one capacitor. Each of the transistors may include a semiconductor portion including a source area, a drain area, and a channel area, and a gate electrode overlapping the semiconductor portion. In embodiments, when the substrate SUB is provided as the silicon substrate, the semiconductor portion may be included in the substrate SUB, and the gate electrode may be included in the pixel circuit layer PCL as a conductive pattern of the pixel circuit layer PCL. In embodiments, when the substrate SUB is provided as the glass substrate and/or the PI substrate, the semiconductor portion and the gate electrode may be included in the pixel circuit layer PCL. The capacitor may include electrodes spaced apart from each other. For example, the capacitor may include electrodes spaced apart from each other on a plane defined by the first and the second directions DR1 and DR2. For example, the capacitor may include electrodes spaced apart from each other in the third direction DR3 with an insulating layer therebetween.

Lines of the pixel circuit layer PCL may include signal lines (e.g., a gate line, a light-emitting control line, and a data line) connected to each of the first to third sub-pixels SP1, SP2, and SP3. The lines may further include a line (e.g., the first power line PL1) connected to the first power voltage node VDDN of FIG. 2, and/or a line (e.g., the second power line PL2) connected to the second power voltage node VSSN of FIG. 2.

The light-emitting element layer LDL may include anode electrodes AE, a pixel-defining layer PDL, a light-emitting structure EMS, and a cathode electrode CE.

The anode electrodes AE may be located on the pixel circuit layer PCL. The anode electrodes AE may contact the circuit elements of the pixel circuit layer PCL. The anode electrode AE may include an opaque conductive material capable of reflecting light, but embodiments are not limited thereto.

The pixel-defining layer PDL may be located on the anode electrodes AE. The pixel-defining layer PDL may include pixel opening OP exposing a portion of each of the anode electrodes AE. Light-emitting areas respectively corresponding to the first to third sub-pixels SP1, SP2, and SP3 may be defined according to the pixel opening OP of the pixel-defining layer PDL. Alternately, it may be understood that light-emitting areas respectively corresponding to the first to third sub-pixels SP1, SP2, and SP3 are defined according to the anode electrodes AE. In an area adjacent to a boundary of the neighboring sub-pixels, the pixel-defining layer PDL may further include a separator, which causes a discontinuity in the light-emitting structure EMS. In this case, it may be understood that light-emitting areas respectively corresponding to the first to third sub-pixels SP1, SP2, and SP3 are defined according to the separators of the pixel-defining layer PDL.

In embodiments, the pixel-defining layer PDL may include an inorganic insulating material. In this case, the pixel-defining layer PDL may include multiple stacked inorganic insulating layers. For example, the pixel-defining layer PDL may include a silicon oxide and a silicon nitride. In other embodiments, the pixel-defining layer PDL may include an organic insulating material. However, the material constituting the pixel-defining layer PDL is not limited thereto.

The light-emitting structure EMS may be located on the anode electrodes AE exposed by the pixel opening OP of the pixel-defining layer PDL. The light-emitting structure EMS may include a light-emitting layer configured to emit light, an electron transport layer configured to transmit electrons, and a hole transport layer configured to transmit holes.

In embodiments, the light-emitting structure EMS may fill the pixel opening OP of the pixel-defining layer PDL, and may be entirely located on the pixel-defining layer PDL. In other words, the light-emitting structure EMS may extend along the first to third sub-pixels SP1, SP2, and SP3. In this case, at least a portion of layers in the light-emitting structure EMS may be disconnected or be bent at the boundaries between the first to third sub-pixels SP1, SP2, and SP3. However, embodiments are not limited thereto. For example, portions of the light-emitting structure EMS corresponding to the first to third sub-pixels SP1, SP2, and SP3 may be separated from each other, and each of them may be located in the pixel opening OP of the pixel-defining layer PDL.

The cathode electrode CE may be located on the light-emitting structure EMS. The cathode electrode CE may extend along the first to third sub-pixels SP1, SP2, and SP3. Like this, the cathode electrode CE may be provided as a common electrode for the first to third sub-pixels SP1, SP2, and SP3.

The cathode electrode CE may be a thin metal layer having a thickness sufficient to transmit light emitted from the light-emitting structure EMS. The cathode electrode CE may be formed of a metal so as to have a relatively small thickness or a transparent conductive material. In embodiments, the cathode electrode CE may include at least one of a variety of transparent conductive materials, including indium tin oxide, indium zinc oxide, indium tin zinc oxide, aluminum zinc oxide, gallium zinc oxide, zinc tin oxide, or gallium tin oxide. In other embodiments, the cathode electrode CE may include at least one of silver (Ag), magnesium (Mg), or mixtures thereof. However, the material constituting the cathode electrode CE is not limited thereto.

Any one of the anode electrodes AE, a portion of the light-emitting structure EMS that overlaps it, or a portion of the cathode electrode CE that overlaps it may be understood to constitute one light-emitting element LD (refer to FIG. 2). In other words, light-emitting elements of the first to third sub-pixels SP1, SP2, and SP3 may each comprise one anode electrode, a portion of the light-emitting structure EMS overlapping therewith, and a portion of the cathode electrode CE overlapping therewith. In each of the first to third sub-pixels SP1, SP2, and SP3, holes injected from the anode electrode AE and electrons injected from the cathode electrode CE are transported into the light-emitting layer of the light-emitting structure EMS to form excitons, and light may be generated when the excitons transition from the excited state to the ground state. The luminance of light may be determined according to the amount of current flowing through the light-emitting layer. The wavelength range of the generated light may be determined according to the configuration of the light-emitting layer.

An encapsulation layer TFE may be located on the cathode electrode CE. The encapsulation layer TFE may cover the light-emitting element layer LDL and/or the pixel circuit layer PCL. The encapsulation layer TFE may be configured to reduce or prevent oxygen and/or moisture from penetrating into the light-emitting element layer LDL. In embodiments, the encapsulation layer TFE may include two or more inorganic encapsulation layers sequentially stacked along the third direction DR3, and an organic encapsulation layer located between two inorganic encapsulation layers adjacent to each other. For example, the inorganic encapsulation layer may include silicon nitride, silicon oxide, and/or silicon oxynitride. For example, the organic encapsulation layer may include acrylic resin, epoxy resin, phenol resin, polyamide resin, polyimide resin, and/or unsaturated polyester resin. However, materials constituting the inorganic encapsulation layer and the organic encapsulation layer are not limited thereto.

The light functional layer OFL may be located on the encapsulation layer TFE. The light functional layer OFL may include a color filter layer CFL and a lens array LA.

The color filter layer CFL may be located between the encapsulation layer TFE and the lens array LA. The color filter layer CFL may be configured to filter light emitted from the light-emitting structure EMS to selectively output light of a wavelength range (e.g., color) corresponding to each sub-pixels. The color filter layer CFL may include color filters CF respectively corresponding to the first to third sub-pixels SP1, SP2, and SP3, each of which may pass light of a wavelength range corresponding to corresponding sub-pixel. For example, the color filter CF corresponding to the first sub-pixel SP1 may pass light of red color, the color filter CF corresponding to the second sub-pixel SP2 may pass light of green color, and the color filter CF corresponding to the third sub-pixel SP3 may pass light of blue color. Depending on light emitted from the light-emitting structure EMS, at least part of the color filters CF may be omitted.

The lens array LA may be located on the color filter layer CFL. The lens array LA may include lenses LS respectively corresponding to the first to third sub-pixels SP1, SP2, and SP3. Each of the lenses LS may output light emitted from the light-emitting structure EMS in the intended path, thereby improving the light-emitting efficiency. The lens array LA may have a relatively high refractive index. In embodiments, the lenses LS may include an organic material. For example, the lenses LS may include an acrylic material, but embodiments are not limited thereto.

In embodiments, relative to the pixel opening OP of the pixel-defining layer PDL, at least some of the color filters CF of the color filter layer CFL and at least some of the lenses LS of the lens array LA may be shifted in a direction parallel to the plane defined by the first and the second directions DR1 and DR2. For example, in a center region of the display area DA, the center of the color filter CF and the center of the lens LS may be aligned or overlapped with the center of the pixel opening OP of the corresponding pixels defining layer PDL when viewed in the third direction DR3. For example, in the center region of the display area DA, the pixel opening OP of the pixel-defining layer PDL may completely overlap the corresponding color filter CF of the color filter layer CFL and the corresponding lens LS of the lens array LA. In a region adjacent to the peripheral area NDA in the display area DA, the center of the color filter CF and the center of the lens LS may be shifted in a planar direction from the center of the pixel opening OP of the corresponding pixel-defining layer PDL when viewed in the third direction DR3. For example, in the region adjacent to the peripheral area NDA in the display area DA, the pixel opening OP of the pixel-defining layer PDL may partially overlap the corresponding color filter CF of the color filter layer CFL and the corresponding lens LS of the lens array LA. Accordingly, in the center of the display area DA, the light emitted from the light-emitting structure EMS may efficiently output in the third direction DR3. Outside from the center of the display area DA, light emitted from the light-emitting structure EMS may efficiently output in a direction inclined by an angle (e.g., a predetermined angle) with respect to the third direction DR3.

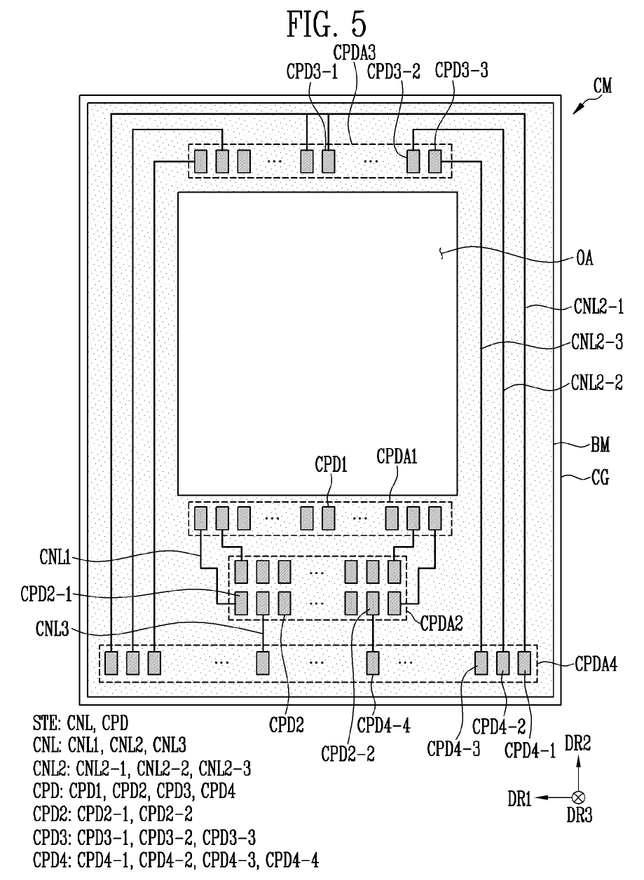

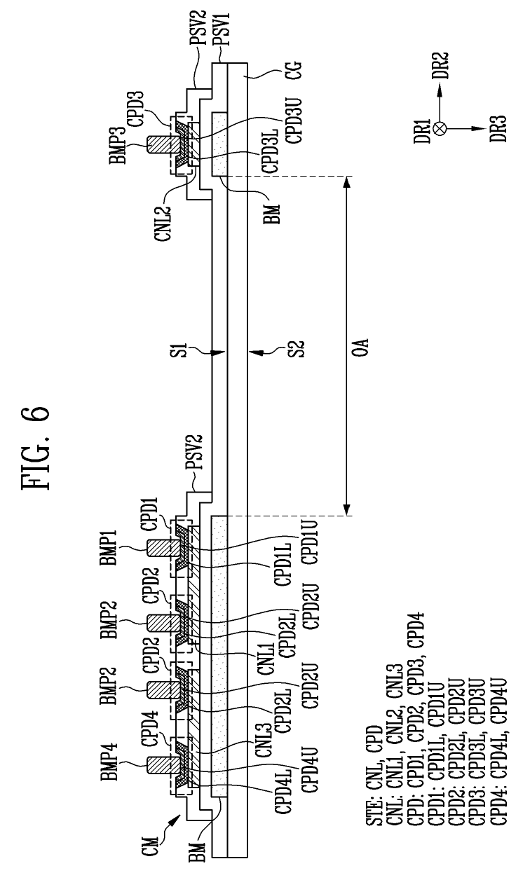

FIG. 5 is a plan view illustrating a cover substrate included in the display device of FIG. 1. FIG. 6 is a cross-sectional view illustrating the cover substrate of FIG. 5.

Referring to FIGS. 5 and 6, a cover substrate CM may include a light-transmitting layer CG, a light-blocking layer BM, a first passivation layer PSV1, a second passivation layer PSV2, and a signal-transmitting element STE.

The light-transmitting layer CG may include a material suitable for transmitting light. The light-transmitting layer CG may have relatively high rigidity. For example, the light-transmitting layer CG may include glass or plastic, but embodiments are not limited thereto.

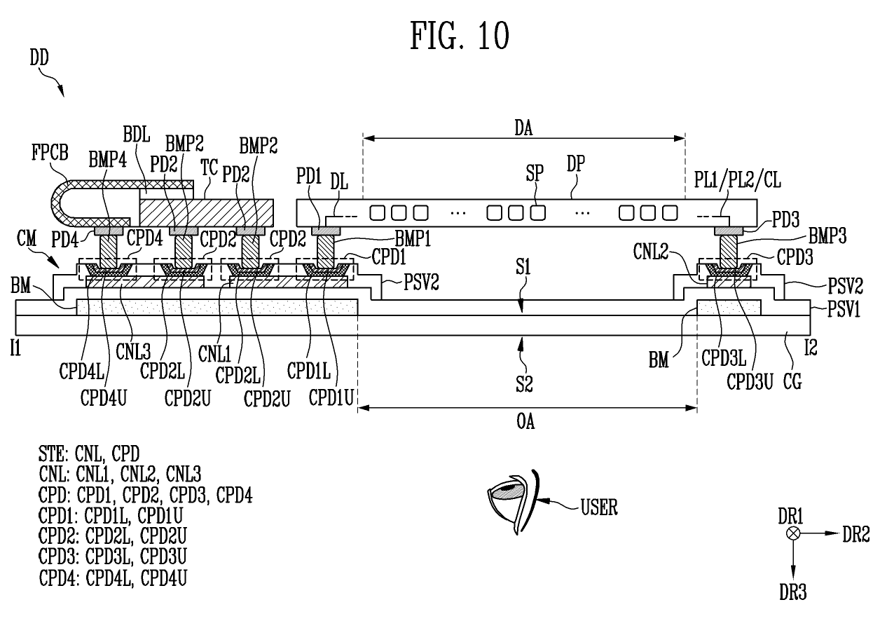

In one or more embodiments, the light-transmitting layer CG may include a facing surface S1, and a display surface S2 opposite to the facing surface S1. In one or more embodiments, the facing surface S1 may be a surface facing the display panel DP, the driving member TC, and the flexible circuit substrate FPCB in a state (refer to FIG. 10) where the cover substrate CM is coupled to the display panel DP, the driving member TC, and the flexible circuit substrate FPCB.

The first passivation layer PSV1 and the second passivation layer PSV2 may be sequentially located on the facing surface S1 along a direction that is opposite to the third direction DR3 (e.g., along a thickness direction), which is a direction from the display surface S2 to the facing surface S1. In one or more embodiments, the first passivation layer PSV1 and the second passivation layer PSV2 may include an inorganic insulating material. For example, the first passivation layer PSV1 and the second passivation layer PSV2 may include silicon nitride, silicon oxide, and/or silicon oxynitride, but embodiments are not limited thereto.

In one or more embodiments, the first passivation layer PSV1 may be entirely located on the facing surface S1. In one or more embodiments, the second passivation layer PSV2 may be selectively located only in a corresponding area on the first passivation layer PSV1 so as to entirely cover transmitting lines CNL.

The signal-transmitting element STE may include a plurality of transmitting lines CNL and a plurality of transmitting pads CPD. The plurality of transmitting lines CNL may be located between the first passivation layer PSV1 and the second passivation layer PSV2. In one or more embodiments, the second passivation layer PSV2 may entirely cover the plurality of transmitting lines CNL. The plurality of transmitting pads CPD may be connected to the plurality of transmitting lines CNL by penetrating the second passivation layer PSV2. In one or more embodiments, at least a portion of each of the plurality of transmitting pads CPD may be exposed without being covered by the second passivation layer PSV2.

The light-blocking layer BM may be located between the light-transmitting layer CG and the first passivation layer PSV1. In one or more embodiments, the light-blocking layer BM may be directly located on the facing surface S1 of the light-transmitting layer CG. The light-blocking layer BM may include a material suitable for blocking light. For example, the light-blocking layer BM may include a nickel layer having a thickness in the third direction DR3 of about 1000 angstroms or more, a copper layer deposited on the facing surface S1 of the light-transmitting layer CG and then oxidized, or an organic light-blocking material (e.g., a black matrix), but embodiments are not limited thereto.

In one or more embodiments, the light-blocking layer BM may overlap the signal-transmitting element STE in the direction opposite to the third direction DR3 (e.g., in the thickness direction). That is, when the cover substrate CM is viewed in a direction from the display surface S2 toward the facing surface S1 on the side of the display surface S2, the signal-transmitting element STE may be obscured by the light-blocking layer BM, and may not be visually recognized.

In one or more embodiments, the light-blocking layer BM may include an opening OA exposing at least a portion of the facing surface S1. The opening OA may overlap at least entirety of the display area DA (refer to FIG. 3) in the direction opposite to the third direction (e.g., in the thickness direction), in a state where the cover substrate CM is coupled to the display panel DP, to the driving member TC, and to the flexible circuit substrate FPCB (refer to FIG. 10).

In one or more embodiments, the plurality of transmitting pads CPD may include first transmitting pads CPD1, second transmitting pads CPD2, third transmitting pads CPD3, and fourth transmitting pads CPD4.

In one or more embodiments, the first transmitting pads CPD1 may be arranged along the first direction DR1, and these first transmitting pads CPD1 may be referred to as a first transmitting pad array CPDA1. In one or more embodiments, the number of the first transmitting pads CPD1 may be same as the number of the first pads PD1 of the display panel DP described with reference to FIG. 3.

In one or more embodiments, the second transmitting pads CPD2 may be arranged along the first and the second direction DR1 and DR2, and theses second transmitting pads CPD2 may be referred to as a second transmitting pad array CPDA2. In one or more embodiments, the number of the second transmitting pads CPD2 may be same as the number of the second pads PD2 of the driving member TC described with reference to FIG. 3.

In one or more embodiments, the second transmitting pads CPD2 may include a 2-1-th transmitting pad CPD2-1 and a 2-2-th transmitting pad CPD2-2.

In one or more embodiments, the 2-1-th transmitting pad CPD2-1 may be provided in plural. In this case, in one or more embodiments, the number of 2-1-th transmitting pads CPD2-1 may be same as the number of the 2-1-th pads PD2-1 of driving member TC described with reference to FIG. 3.

In one or more embodiments, the 2-2-th transmitting pad CPD2-2 may be provided in plural. In this case, in one or more embodiments, the number of 2-2-th transmitting pads CPD2-2 may be same as the number of the 2-2-th pads PD2-2 of driving member TC described with reference to FIG. 3.

In one or more embodiments, the third transmitting pads CPD3 may be arranged along the first direction DR1, and theses third transmitting pads CPD3 may be referred to as a third transmitting pad array CPDA3. In one or more embodiments, the number of the third transmitting pads CPD3 may be same as the number of the third pads PD3 of the display panel DP described with reference to FIG. 3.

In one or more embodiments, the third transmitting pads CPD3 may include a 3-1-th transmitting pads CPD3-1, a 3-2-th transmitting pad CPD3-2, and a 3-3-th transmitting pad CPD3-3.

In one or more embodiments, the 3-1-th transmitting pad CPD3-1 may be provided in plural. In this case, in one or more embodiments, the number of 3-1-th transmitting pads CPD3-1 may be same as the number of the 3-1-th pads PD3-1 of the display panel DP described with reference to FIG. 3.

In one or more embodiments, the 3-2-th transmitting pad CPD3-2 may be provided in plural. In this case, in one or more embodiments, the number of 3-2-th transmitting pads CPD3-2 may be same as the number of the 3-2-th pads PD3-2 of the display panel DP described with reference to FIG. 3.

In one or more embodiments, the 3-3-th transmitting pad CPD3-3 may be provided in plural. In this case, in one or more embodiments, the number of 3-3-th transmitting pads CPD3-3 may be same as the number of the 3-3-th pads PD3-3 of the display panel DP described with reference to FIG. 3.

In one or more embodiments, the fourth transmitting pads CPD4 may be arranged along the first direction DR1, and theses fourth transmitting pads CPD4 may be referred to as a fourth transmitting pad array CPDA4. In one or more embodiments, the number of the fourth transmitting pads CPD4 may be same as the number of the fourth pads PD4 of the flexible circuit substrate FPCB described with reference to FIG. 3.

In one or more embodiments, the fourth transmitting pads CPD4 may include a 4-1-th transmitting pad CPD4-1, a 4-2-th transmitting pad CPD4-2, a 4-3-th transmitting pad CPD4-3, and a 4-4-th transmitting pad CPD4-4.

In one or more embodiments, the 4-1-th transmitting pad CPD4-1 may be provided in plural. In this case, in one or more embodiments, the number of 4-1-th transmitting pads CPD4-1 may be same as the number of the 4-1-th pads PD4-1 of the flexible circuit substrate FPCB described with reference to FIG. 3.

In one or more embodiments, the 4-2-th transmitting pad CPD4-2 may be provided in plural. In this case, in one or more embodiments, the number of 4-2-th transmitting pads CPD4-2 may be same as the number of the 4-2-th pads PD4-2 of the flexible circuit substrate FPCB described with reference to FIG. 3.

In one or more embodiments, the 4-3-th transmitting pad CPD4-3 may be provided in plural. In this case, in one or more embodiments, the number of 4-3-th transmitting pads CPD4-3 may be same as the number of the 4-3-th pads PD4-3 of the flexible circuit substrate FPCB described with reference to FIG. 3.

In one or more embodiments, the 4-4-th transmitting pad CPD4-4 may be provided in plural. In this case, in one or more embodiments, the number of 4-4-th transmitting pads CPD4-4 may be same as the number of the 4-4-th pads PD4-4 of the flexible circuit substrate FPCB described with reference to FIG. 3.

In one or more embodiments, as shown in FIG. 6, first to fourth conductive connecting members BMP1, BMP2, BMP3, and BMP4 may be located on the first to fourth transmitting pads CPD1, CPD2, CPD3, and CPD4, respectively. The first to fourth conductive connecting members BMP1, BMP2, BMP3, and BMP4 may serve to electrically couple the cover substrate CM to the display panel DP, the driving member TC, and the flexible circuit substrate FPCB. This will be described later with reference to FIG. 10.

Each of the plurality of transmitting lines CNL may serve to electrically connect two or more transmitting pads CPD among the plurality of transmitting pads CPD to each other. In one or more embodiments, the plurality of transmitting lines CNL may include first transmitting lines CNL1, second transmitting lines CNL2, and third transmitting lines CNL3.

The first transmitting lines CNL1 may electrically connect the first transmitting pads CPD1 and the 2-1-th transmitting pads CPD2-1. In one or more embodiments, the first transmitting lines CNL1 may be provided in one-to-one correspondence with electrical connection units, each of which consists of one first transmitting pad CPD1 and one 2-1-th transmitting pad CPD2-1 electrically connected thereto.

The second transmitting lines CNL2 may respectively electrically connect the 3-1-th transmitting pads CPD3-1 and the 4-1-th transmitting pads CPD4-1, the 3-2-th transmitting pads CPD3-2 and the 4-2-th transmitting pads CPD4-2, and the 3-3-th transmitting pads CPD3-3 and the 4-3-th transmitting pads CPD4-4.

In one or more embodiments, the second transmitting lines CNL2 may include a 2-1-th transmitting line CNL2-1, 2-2-th transmitting lines CNL2-2, and 2-3-th transmitting lines CNL2-3.

The 2-1-th transmitting line CNL2-1 may electrically connect the 3-1-th transmitting pads CPD3-1 and the 4-1-th transmitting pads CPD4-1. In this case, in one or more embodiments, two or more 3-1-th transmitting pads CPD3-1 and two or more 4-1-th transmitting pads CPD4-1 may be electrically connected to one 2-1-th transmitting line CNL2-1. However, embodiments are not limited thereto. In one or more other embodiments, the 2-1-th transmitting line CNL2-1 may be provided in plural.

The 2-2-th transmitting lines CNL2-2 may electrically connect the 3-2-th transmitting pads CPD3-2 and the 4-2-th transmitting pads CPD4-2. In one or more embodiments, the 2-2-th transmitting lines CNL2-2 may be provided in one-to-one correspondence with electrical connection units, each of which consist of one 4-2-th transmitting pad CPD4-2 and one or more 3-2 transmitting pads CPD3-2 electrically connected thereto.

The 2-3-th transmitting lines CNL2-3 may electrically connect the 3-3-th transmitting pads CPD3-3 and the 4-3-th transmitting pads CPD4-3. In one or more embodiments, the 2-3-th transmitting lines CNL2-3 may be provided in one-to-one correspondence with electrical connection units, each of which consist of one 4-3-th transmitting pad CPD4-3 and one 3-3-th transmitting pad CPD3-3 electrically connected thereto.

The third transmitting lines CNL3 may electrically connect the 2-2-th transmitting pads CPD2-2 and the 4-4-th transmitting pads CPD4-4. In one or more embodiments, the third transmitting lines CNL3 may be provided in one-to-one correspondence with electrical connection units, each of which consist of one 2-2-th transmitting pad CPD2-2 and one 4-4-th transmitting pad CPD4-4 electrically connected thereto.

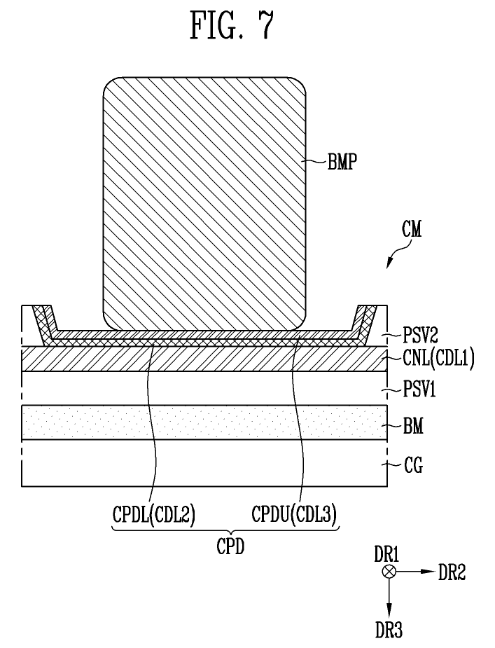

FIG. 7 is a cross-sectional view illustrating a signal transmission element included in the cover substrate of FIG. 6.

Referring to FIG. 7, the signal-transmitting element STE may include the transmitting line CNL, and the transmitting pad CPD electrically contacting the transmitting line CNL.

In one or more embodiments, the transmitting line CNL may include a first conductive material CDL1. The first conductive material CDL1 may be a material having a relative high conductivity. For example, the first conductive material CDL1 may include copper, but embodiments are not limited thereto.

In one or more embodiments, the transmitting pad CPD may include a lower transmitting pad layer CPDL and an upper transmitting pad layer CPDU.

The lower transmitting pad layer CPDL may directly contact the transmitting line CNL by penetrating the second passivation layer PSV2. In one or more embodiments, the lower transmitting pad layer CPDL may cover a portion of an upper surface of the transmission line CNL and side surfaces of the second passivation layer PSV2 adjacent thereto.

In one or more embodiments, the lower transmitting pad layer CPDL may include a second conductive material CDL2. The second conductive material CLD2 may include a material that may serve as a seed layer in the formation process of the transmitting pad CPD. For example, the second conductive material CDL2 may include nickel, but embodiments are not limited thereto.

The upper transmitting pad layer CPDU may cover the lower transmitting pad layer CPDL. In one or more embodiments, the upper transmitting pad layer CPDU may cover a portion of the lower transmitting pad layer CPDL covering the portion of the upper surface of the transmitting line CNL, and a portion of the lower transmitting pad layer CPDL covering the side surfaces of the second passivation layer PSV2.

In one or more embodiments, the upper transmitting pad layer CPDU may include a third conductive material CDL3. The third conductive material CDL3 may be a material that is different from the second conductive material CDL2. The third conductive material CDL3 may include a material capable of performing a role of a barrier to the second conductive material CDL2, and a role of securing sufficient adhesion with the conductive connecting member BMP located on the upper transmitting pad layer CPDU. For example, the upper transmitting pad layer CPDU may include titanium, but embodiments are not limited thereto.

Referring to FIG. 6 again, the first to fourth transmitting pads CPD1, CPD2, CPD3, and CPD4 may be described in the same way as the transmitting pad CPD described with reference to FIG. 7. For example, the first to fourth transmitting pads CPD1, CPD2, CPD3, and CPD4 may include first to fourth upper transmitting pad layers CPD1U, CPD2U, CPD3U, and CPD4U and first to fourth lower transmitting pad layers CPD1L, CPD2L, CPD3L, and CPD4L, respectively.

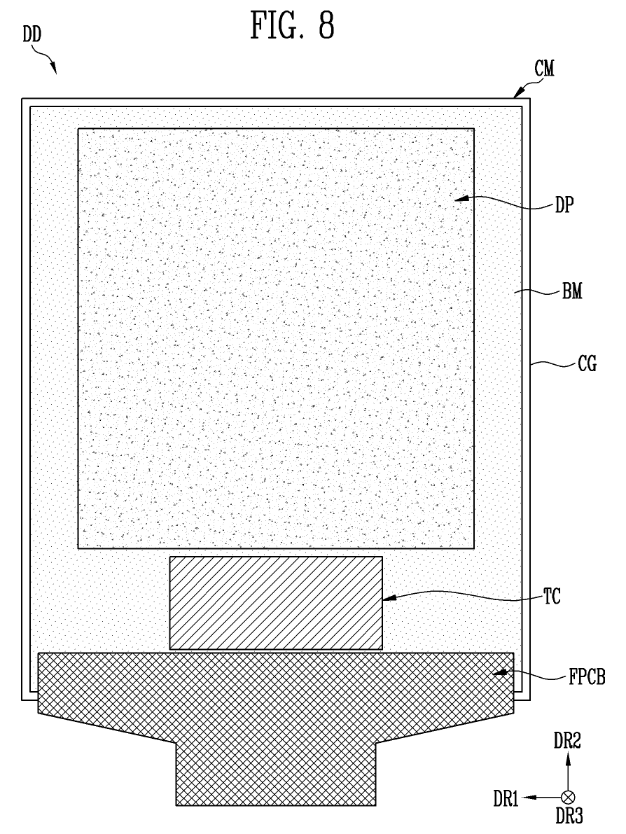

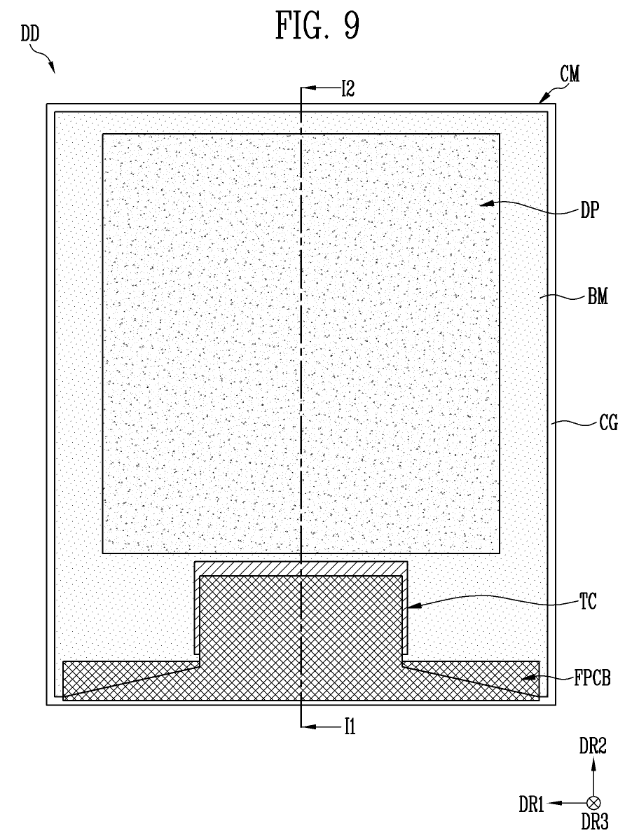

FIGS. 8 and 9 are plan views illustrating a state in which the display panel, the driving member, and the flexible circuit substrate of FIG. 3 are coupled to the cover substrate of FIG. 5.

Referring to FIG. FIGS. 3,5, and 8, the display device DD may include the cover substrate CM, and the display panel DP, the driving member TC, and the flexible circuit substrate FPCB coupled to the cover substrate CM. The display panel DP, the driving member TC, and the flexible circuit substrate FPCB may be located on the same surface of the cover substrate CM, and the cover substrate CM may cover the display panel DP, the driving member TC, and the flexible circuit substrate FPCB.

In a state where the display panel DP is coupled to the cover substrate CM, an emission surface of the display panel DP on which light emitted from the sub-pixels SP of the display panel DP is visually recognized may face the light-transmitting layer CG with the light-blocking layer BM therebetween. That is, light generated in the sub-pixels SP of the display panel DP may travel in a direction toward the cover substrate CM, but may not substantially travel in a direction opposite to the direction toward the cover substrate CM.

The display panel DP may be coupled to the cover substrate CM such that the first pad array PDA1 and the first transmitting pad array CPDA1 overlap in the thickness direction, and such that the third pad array PDA3 and the third transmitting pad array CPDA3 overlap in the thickness direction.

In this case, the first pads PD1 included in the first pad array PDA1 may overlap the first transmitting pads CPD1 included in the first transmitting pad array CPDA1, respectively.

The third pads PD3 included in the third pad array PDA3 may overlap the third transmitting pads CPD3 included in the third transmitting pad array CPDA3, respectively, in one or more embodiments, the 3-1-th pads PD3-1, the 3-2-th pads PD3-2, and the 3-3-th pads PD3-3 may overlap the 3-1-th transmitting pads CPD3-1, the 3-2-th transmitting pads CPD3-2, and the 3-3-th transmitting pads CPD3-3, respectively.

The driving member TC may be coupled to the cover substrate CM such that the second pad array PDA2 and the second transmitting pad array CPDA2 overlap in the thickness direction.

In this case, the second pads PD2 included in the second pad array PDA2 may overlap the second transmitting pads CPD2 included in the second transmitting pad array CPDA2, respectively. In one or more embodiments, the 2-1-th pads PD2-1 and the 2-2-th pads PD2-2 may overlap the 2-1-th transmitting pads CPD2-1 and the 2-2-th transmitting pads CPD2-2, respectively.

The flexible circuit substrate FPCB may be coupled to the cover substrate CM such that the fourth pad array PDA4 and the fourth transmitting pad array CPDA4 overlap in the thickness direction.

In this case, the fourth pads PD4 included in the fourth pad array PDA4 may overlap the fourth transmitting pads CPD4 included in the fourth pad array CPD4, respectively. In one or more embodiments, the 4-1-th pads PD4-1, the 4-2-th pads PD4-2, the 4-3-th pads PD4-3, and the 4-4-th pads PD4-4 may overlap the 4-1-th transmitting pads CPD4-1, the 4-2-th transmitting pads CPD4-2, the 4-3-th transmitting pads CPD4-3, and the 4-4-th transmitting pads CPD4-4, respectively.

Referring to FIG. 9, in one or more embodiments, the flexible circuit substrate FPCB may be bent in at least some areas. Accordingly, at least a portion of the flexible circuit substrate FPCB may overlap at least a portion of the driving member TC in the thickness direction. In this case, in one or more embodiments, a step compensation layer BDL (refer to FIG. 10) may be located between the portion of the flexible circuit substrate FPCB and the portion of the driving member TC.

FIG. 10 is a cross-sectional view taken along the line I1-I2 of FIG. 9.

Referring to FIG. 10, the display device may include the first to fourth conductive connecting member BMP1, BMP2, BMP3, and BMP4.

The first conductive connecting member BMP1 may be located between the first pad PD1 and the first transmitting pad CPD1 overlapping thereto in the thickness direction. The first conductive connecting member BMP1 may electrically connect the first pad PD1 and the first transmitting pad CPD1 overlapping thereto in the thickness direction. In this case, when each of the first pad PD1 and the first transmitting pad CPD1 is provided in plural, a plurality of first conductive connecting members BMP1 may be provided so as to correspond one-to-one to electrical connecting units each consisting of one first pad PD1 and one first transmitting pad CPD1 overlapping thereto in the thickness direction.

The second conductive connecting member BMP2 may be located between the second pad PD2 and the second transmitting pad CPD2 overlapping thereto in the thickness direction. The second conductive connecting member BMP2 may electrically connect the second pad PD2 and the second transmitting pad CPD2 overlapping thereto in the thickness direction. In this case, when each of the second pad PD2 and the second transmitting pad CPD2 is provided in plural, a plurality of second conductive connecting members BMP2 may be provided so as to correspond one-to-one to electrical connecting unit each consisting of one second pad PD2 and one second transmitting pad CPD2 overlapping thereto in the thickness direction.

The third conductive connecting member BMP3 may be located between the third pad PD3 and the third transmitting pad CPD3 overlapping thereto in the thickness direction. The third conductive connecting member BMP3 may electrically connect the third pad PD3 and the third transmitting pad CPD3 overlapping thereto in the thickness direction. In this case, when each of the third pad PD3 and the third transmitting pad CPD3 is provided in plural, a plurality of third conductive connecting members BMP3 may be provided so as to correspond one-to-one to electrical connecting units each consisting of one third pad PD3 and one third transmitting pad CPD3 overlapping thereto in the thickness direction.

The fourth conductive connecting member BMP4 may be located between the fourth pad PD4 and the fourth transmitting pad CPD4 overlapping thereto in the thickness direction. The fourth conductive connecting member BMP4 may electrically connect the fourth pad PD4 and the fourth transmitting pad CPD4 overlapping thereto in the thickness direction. In this case, when each of the fourth pad PD4 and the fourth transmitting pad CPD4 is provided in plural, a plurality of fourth conductive connecting members BMP4 may be provided so as to correspond one-to-one to electrical connecting units each consisting of one fourth pad PD4 and one fourth transmitting pad CPD4 overlapping thereto in the thickness direction.

In one or more embodiments, each of the first to fourth conductive connecting members BMP1, BMP2, BMP3, and BMP4 may serve to electrically couple the display panel DP, the driving member TC, and the flexible circuit substrate FPCB to the cover substrate CM. For example, after the first to fourth conductive connecting members BMP1, BMP2, BMP3, and BMP4 are melted, the display panel DP, the driving member TC, and the flexible circuit substrate FPCB are respectively located at corresponding positions of the cover substrate CM, and then the first to fourth conductive connecting members BMP1, BMP2, BMP3, and BMP4 are cooled, whereby the display panel DP, the driving member TC, and the flexible circuit substrate FPCB may be electrically coupled to the cover substrate CM.

In this case, in one or more embodiments, the melting point(s) of each of the first to fourth conductive connecting members BMP1, BMP2, BMP3, and BMP4 may be greater than or equal to about 110℃ and less than or equal to about 150℃. As the melting point of each of the first to fourth conductive connecting members BMP1, BMP2, BMP3, and BMP4 satisfies the above-described range, the first to fourth conductive connecting members BMP1, BMP2, BMP3, and BMP4 may not be melted by heat generated when the display device DD operates, and it is also possible to reduce or prevent damage to the sub-pixels SP of the display device DD due to high temperature in a process in which the display panel DP, the driving member TC, and the flexible circuit substrate FPCB are electrically coupled to the cover substrate CM.

With the display device DD configured as described above, the display panel DP, the driving member TC, and the flexible circuit substrate FPCB may be electrically connected to each other through the signal-transmitting element STE. That is, the cover substrate CM including the signal-transmitting element STE may provide at least a portion of electrical connection paths of the display panel DP, the driving member TC, and the flexible circuit substrate FPCB.

For example, the 2-1-th pads PD2-1 of the driving member TC may be electrically connected to the first pads PD1 of the display panel DP through the 2-1-th transmitting pads CPD2-1, the first transmitting lines CNL1, and the first transmitting pads CPD1. Accordingly, the first driving signal (e.g., the data signal) output from the 2-1-th pads PD2-1 of the driving member TC may be transmitted to the first pads PD1 of the display panel DP and the data lines DL electrically connected thereto.

For example, the 4-1-th to 4-3-th pads PD4-1, PD4-2, and PD4-3 of the flexible circuit substrate FPCB may be electrically connected to the third pads PD3 of the display panel DP through the 4-1-th to 4-3-th transmitting pads CPD4-1, CPD4-2, and CPD4-3, the second transmitting lines CNL2, and the third transmitting pads CPD3. Accordingly, the second driving signal (e.g., the gate control signal GCS (e.g., the scan-driving signal), the first power voltage VDD (e.g., the first power signal), and the second power voltage VSS (e.g., the second power signal)), which is output from the 4-1-th to 4-3-th pads PD4-1, PD4-2, and PD4-3 of the flexible circuit substrate FPCB, may be transmitted to the third pads PD3 of the display panel DP and the first power line PL1, the second power line PL2, and the connecting line CL electrically connected thereto.

For example, the 4-4-th pads PD4-4 of the flexible circuit substrate FPCB may be electrically connected to the 2-2-th pads PD2-2 of the driving member TC through the 4-4-th transmitting pads CPD4-4, the third transmitting lines CNL3, and the 2-2-th transmitting pads CPD2-2. Accordingly, the second driving signal (e.g., the image data DATA and the data control signal DCS) output from the 4-4-th pads PD4-4 of the flexible circuit substrate FPCB may be transmitted to the 2-2-th pads CPD2-2 of the driving member TC.

In one or more embodiments, the light-blocking layer BM may overlap the signal-transmitting element STE in the thickness direction. That is, when the user USER of the display device DD looks at the cover substrate CM in a direction from the display surface S2 toward the facing surface S1 on the display surface S2, the signal-transmitting element STE may be obscured by the light-blocking layer BM and might not be visually recognized. Accordingly, it is possible to reduce or prevent degradation of the display quality of the display device DD due to the signal-transmitting element STE being visually recognized.

In one or more embodiments, the light-blocking layer BM may include the opening OA, wherein the opening OA may overlap at least the entirety of the display area DA in the thickness direction. Accordingly, it is possible to reduce or prevent the likelihood of an image displayed in the display area DA being blocked by the light-blocking layer BM.

In one or more embodiments, the light-blocking layer BM may overlap the peripheral area NDA of the display panel DP, the driving member TC, and the flexible circuit substrate FPCB in the thickness direction. Accordingly, when the user USER of the display device DD looks at the cover substrate CM from the display surface S2 toward the facing surface S1, the peripheral area NDA of the display panel DP, the driving member TC, and the flexible circuit substrate FPCB may be hidden by the light- blocking layer BM, and might not be visually recognized. Accordingly, the display quality of the display device DD may be improved.

A display device according to one or more embodiments is applicable to various types of electronic device. In one or more embodiments, an electronic device includes the above-described display device and may further include other modules or devices having additional functions in addition to the display device.

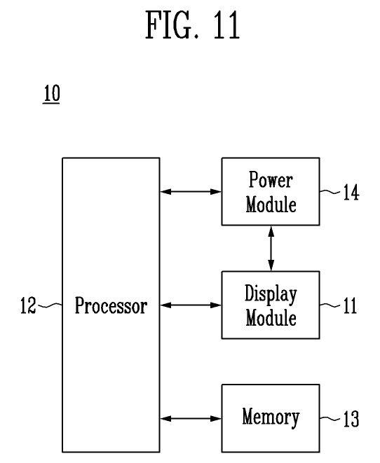

FIG. 11 is a block diagram of an electronic device according to one or more embodiments. Referring to FIG. 11, an electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module, and may generate power to operate the electronic device 10.

At least one of the above-described components of the electronic device 10 may be included in the display device according to embodiments as described above. In addition, in terms of functionality, some of the individual modules included in one module may be included in the display device and others may be provided separately from the display device. For example, the display module 11 is included in the display device, whereas the processor 12, the memory 13, and the power module 14 are not included in the display device, and are instead provided separately in the electronic device 10.

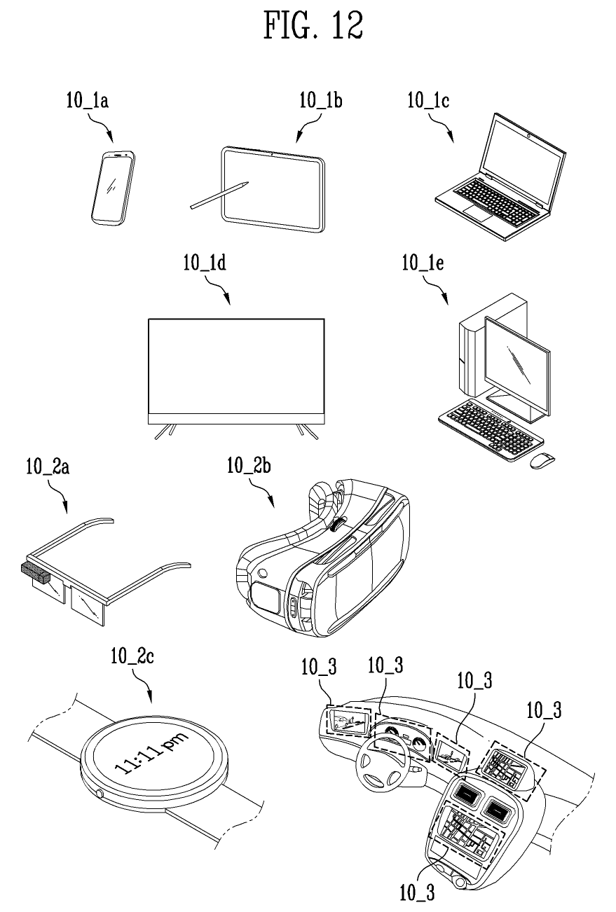

FIG. 12 shows schematic views of various embodiments of an electronic device.

Referring to FIG. 12, various types of electronic devices to which embodiments of a display device are applied may include an electronic device to display images, such as a smartphone 10_1a, a tablet PC 10_1b, a laptop computer 10_1c, a television (TV) 10_1d, and a desktop monitor 10_1e, a wearable electronic device including a display module, such as smart glasses 10_2a, a head-mounted display (HMD) 10_2b, and a smart watch 10_2c, and an automotive electronic device 10_3 including a display module, such as a center information display (CID) located at the instrument cluster, the center fascia, and the dashboard of a vehicle, and a room mirror display.

While embodiments have been described above, those skilled in the art will appreciate that various modifications, additions, and substitutions are possible, without departing from the scope and spirit of the present disclosure claimed in the appended claims, with functional equivalents thereof to be included therein.

What is claimed is:

1. A display device, comprising:
a display panel comprising a display area for displaying an image, and a peripheral area around the display area;
a driving member to provide a first driving signal; and
a cover substrate covering the display panel and the driving member, and comprising:
a light-transmitting layer comprising a facing surface facing the display panel and the driving member, and a display surface opposite to the facing surface;
a first passivation layer and a second passivation layer sequentially on the facing surface along a thickness direction from the display surface toward the opposite surface;
a signal-transmitting element electrically connecting the display panel and the driving member, and comprising transmitting lines between the first passivation layer and the second passivation layer, and transmitting pads connected to the transmitting lines by penetrating the second passivation layer; and
a light-blocking layer between the light-transmitting layer and the first passivation layer, overlapping the signal-transmitting element in the thickness direction, and defining an opening overlapping an entirety of the display area in the thickness direction.

2. The display device according to claim 1, wherein the display panel further comprises:
sub-pixels in the display area; and
first pads in the peripheral area, and electrically connected to the sub-pixels, and
wherein the driving member comprises second pads comprising 2-1-th pads for outputting the first driving signal.

3. The display device according to claim 2, wherein the transmitting pads comprise:
first transmitting pads electrically connected to the first pads; and
second transmitting pads electrically connected to the second pads, and
wherein the transmitting lines comprise first transmitting lines electrically connecting 2-1-th transmitting pads electrically connected to the 2-1-th pads to the first transmitting pads.

4. The display device according to claim 3, wherein the first pads and the first transmitting pads overlap in the thickness direction, and
wherein the second pads and the second transmitting pads overlap in the thickness direction.

5. The display device according to claim 4, further comprising:
first conductive connecting members between the first pads and the first transmitting pads; and
second conductive connecting members between the second pads and the second transmitting pads.

6. The display device according to claim 5, wherein melting points of the first conductive connecting members and the second conductive connecting members is greater than or equal to about 110℃ and less than or equal to about 150℃.

7. The display device according to claim 2, wherein the display panel further comprises data lines electrically connected to the first pads in the peripheral area and electrically connected to the sub-pixels in the display area.

8. The display device according to claim 7, wherein the first driving signal comprises a data signal transmitted from the driving member to the display panel through the signal-transmitting element.

9. The display device according to claim 1, further comprising a flexible circuit substrate to provide a second driving signal, wherein the cover substrate covers the flexible circuit substrate.

10. The display device according to claim 9, wherein the display panel and the flexible circuit substrate are electrically connected to each other through the signal-transmitting element.

11. The display device according to claim 9, wherein the flexible circuit substrate is bent, and comprises at least a portion overlapping at least a portion of the driving member in the thickness direction.

12. The display device according to claim 10, wherein the display panel comprises:
sub-pixels in the display area;
a scan driver in the peripheral area, and electrically connected to the sub-pixels; and
third pads in the peripheral area, and electrically connected to the sub-pixels or the scan driver, and
wherein the flexible circuit substrate comprises fourth pads configured to output the second driving signal.

13. The display device according to claim 12, wherein the transmitting pads comprises:
third transmitting pads electrically connected to the third pads; and
fourth transmitting pads electrically connected to the fourth pads, and
wherein the transmitting lines comprise second transmitting lines electrically connecting the third transmitting pads and the fourth transmitting pads.

14. The display device according to claim 13, wherein the third pads and the third transmitting pads overlap in the thickness direction, and
wherein the fourth pads and the fourth transmitting pads overlap in the thickness direction.

15. The display device according to claim 14, further comprising:
third conductive connecting members between the third pads and the third transmitting pads; and
fourth conductive connecting members between the fourth pads and the fourth transmitting pads.

16. The display device according to claim 15, wherein melting points of the third conductive connecting members and the fourth conductive connecting members are greater than or equal to about 110℃ and less than or equal to about 150℃.

17. The display device according to claim 12, wherein the display panel comprises at least one first power line, at least one second power line, and at least one connecting line,
wherein, in the peripheral area, the third pads are electrically connected to the first power line, the second power line, or the connecting line, and the connecting line is electrically connected to the scan driver, and
wherein, in the display area, the first power line and the second power line are electrically connected to the sub-pixels.

18. The display device according to claim 17, wherein the second driving signal comprises a first power signal, a second power signal, and a scan-driving signal transmitted from the fourth pads to the third pads through the signal-transmitting element.

19. The display device according to claim 1, wherein the light-blocking layer overlaps the peripheral area of the display panel and the driving member in the thickness direction.

20. An electronic device, comprising:
a power supply module for supplying power; and
a display device for receiving the power, and comprising:
a display panel comprising a display area for displaying an image, and a peripheral area around the display area;
a driving member to provide a first driving signal; and
a cover substrate covering the display panel and the driving member, and comprising:
a light-transmitting layer comprising a facing surface facing the display panel and the driving member, and a display surface opposite to the facing surface;
a first passivation layer and a second passivation layer sequentially on the facing surface along a thickness direction from the display surface toward the opposite surface;
a signal-transmitting element electrically connecting the display panel and the driving member, and comprising transmitting lines between the first passivation layer and the second passivation layer, and transmitting pads connected to the transmitting lines by penetrating the second passivation layer; and
a light-blocking layer between the light-transmitting layer and the first passivation layer, overlapping the signal-transmitting element in the thickness direction, and defining an opening overlapping an entirety of the display area in the thickness direction.
